(19) United States
(12) Patent Application Publication
(10) Pub. No.: US 2023/0050165 A1
(43) Pub. Date: Feb. 16, 2023

(54) METHOD FOR PRODUCING AN OHMIC CONTACT ON A CRYSTALLOGRAPHIC C-SIDE OF A SILICON CARBIDE SUBSTRATE, AND OHMIC CONTACT

(71) Applicant: Robert Bosch GmbH, Stuttgart (DE)

(72) Inventors: Humberto Rodriguez Alvarez, Kornwestheim (DE); Jan-Hendrik Alsmeier, Pfullingen (DE)

(21) Appl. No.: 17/792,178

(22) PCT Filed: Mar. 19, 2021
(86) PCT No.: PCT/EP2021/057089

§ 371 Date: Jul. 12, 2022

(30) Foreign Application Priority Data
Mar. 20, 2020 (DE) 10 2020 203 618.7

(51) Int. Cl. H01L 29/45; H01L 29/16; H01L 29/786; H01L 21/02; H01L 21/04; H01L 21/268

(52) U.S. Cl. CPC H01L 29/458; H01L 21/268; H01L 21/0485; H01L 21/02532; H01L 29/1608; H01L 29/78696

(57) ABSTRACT

A method for producing an ohmic contact on a crystallographic C-side of a silicon carbide substrate. The method includes: applying a layer stack to the crystallographic C-side of the silicon carbide substrate, the layer stack including at least one semiconducting layer containing germanium, and at least one metallic layer; and producing a point-by-point liquid phase of the layer stack, a surface of the layer stack being scanned using laser beams.

### FIELD

The present invention relates to a method for producing an ohmic contact on a crystallographic C-side of a silicon carbide substrate, and to an ohmic contact on the crystallographic C-side of the silicon carbide substrate.

### BACKGROUND INFORMATION

U.S. Pat. No. US 8,440,524 B2 describes a method for manufacturing semiconductor components, in particular MOSFETs, in which an ohmic contact is produced on one side of the semiconductor substrate by heating a metal layer situated on the side of the semiconductor substrate, using a laser.

Thus, in the production of ohmic contacts on silicon carbide substrates, one or more metal layers are applied to the semiconductor substrate. The metal layers are subsequently heated by use of a laser, resulting in the ohmic contacts.

It is disadvantageous that in the production of the ohmic contacts, carbon regions form due to the reaction of silicon carbide and metal when heat is supplied. The adhesion and the reliability of the ohmic contacts are thus adversely affected.

An object of the present invention is to overcome these disadvantages.

### SUMMARY

A method according to the present invention for producing an ohmic contact on a crystallographic C-side of a silicon carbide substrate comprises applying a layer stack to the crystallographic C-side of the silicon carbide substrate, the layer stack including at least one semiconducting layer containing germanium and at least one metallic layer, and producing a point-by-point liquid phase of the layer stack, a surface of the layer stack being scanned using laser beams.

An advantage is that the ohmic contact has good adhesion to the silicon carbide substrate.

In one refinement of the present invention, semiconducting layers and metallic layers are applied to the crystallographic C-side of the silicon carbide substrate in alternation.

In one embodiment of the present invention, nickel or titanium are applied as metallic layers.

An advantage is that the melting temperature is low.

In one refinement of the present invention, vanadium, tantalum, niobium, zirconium, molybdenum, tungsten, or an alloy of these metals with nickel or titanium are applied as metallic layers. In other words, there is at least one metallic layer that includes nickel or titanium, and there are additionally metallic layers that include vanadium, tantalum, niobium, zirconium, molybdenum, tungsten, or an alloy of these metals with nickel or titanium.

It is advantageous that these metallic elements bind the carbon.

In one embodiment of the present invention, layer thicknesses of the semiconducting layers and layer thicknesses of the metallic layers of 3 nm to 100 nm are applied.

The advantage is that reliable and long-lasting contact with the SiC is produced. In addition, the coupling-in of the laser light is optimal.

In one refinement of the present invention, the at least one semiconducting layer containing germanium is applied to the silicon carbide substrate first.

It is advantageous that the melting temperatures and the soldering temperatures have a value in the range between 900° C. and 1000° C.

In one embodiment of the present invention, the laser beams for producing the point-by-point liquid phase of the layer stack have a diameter of 10 µm to 100 µm.

An advantage is that the throughput is high despite moderate laser power, since the scanning of the surface may take place more quickly using larger diameters.

In one refinement of the present invention, the laser beams transmit at least an energy density of 1 J/cm2onto a surface of the layer stack.

In one embodiment of the present invention, the pulse repetition frequency of the laser beams is between 10 kHz and 50 kHz.

An advantage is that the system costs are low.

The ohmic contact is situated on a crystallographic C-side of a silicon carbide substrate. According to the present invention, as the result of a laser treatment, a layer that includes semiconducting elements containing germanium and metallic elements is situated on the crystallographic C-side of the silicon carbide substrate.

An advantage is that the resulting contact has a low ohmic resistance and high adhesion. This is particularly suitable for producing a drain contact of the power semiconductor element.

In one refinement of the present invention, the metallic elements are nickel or titanium.

It is advantageous that the melting temperature of the mixture is low.

In a further embodiment, the metallic elements include vanadium, tantalum, niobium, zirconium, molybdenum, or tungsten.

It is advantageous that these metallic elements bind the carbon. In other words, these metals function as getter elements for the carbon.

In one refinement of the present invention, a contact resistance between the silicon carbide substrate and the layer has a value of less than 100 pQ/cm2 at a current density greater than 3 A/mm2.

The advantage is that a vertical component, for example a MOSFET, that includes such a contact on the rear side has a small resistance in the case of transmission.

Further advantages result from the following description of exemplary embodiments and the disclosure herein.

### BRIEF DESCRIPTION OF THE DRAWINGS

The present invention is explained below with reference to preferred specific embodiments and the figures.

FIG. 1 shows a method for producing an ohmic contact on a crystallographic C-side of a silicon carbide substrate.

FIG. 2 shows an ohmic contact on the crystallographic C-side of the silicon carbide substrate.

### DETAILED DESCRIPTION OF EXAMPLE EMBODIMENTS

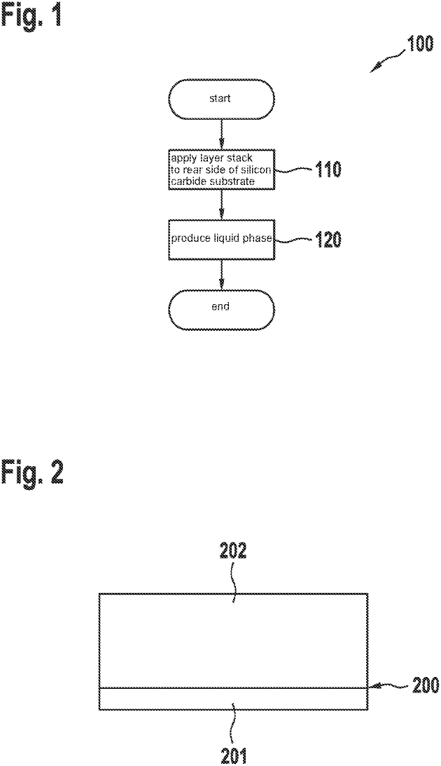

FIG. 1 shows a method 100 for producing an ohmic contact on a rear side, in particular a crystallographic C-side, of a silicon carbide substrate. The method starts with a step 110 in which a layer stack is applied to the rear side of the silicon carbide substrate. The layer stack includes at least one semiconducting layer and at least one metallic layer. The semiconducting layers and the metallic layers are applied to the silicon carbide substrate in alternation. In other words, the layer stack has an alternating sequence of semiconducting layers and metallic layers. The number of semiconducting layers and the number of metallic layers may be different. At least one of the semiconducting layers includes germanium, and the metallic layers include at least nickel or titanium. In addition, the metallic layers may include vanadium, tantalum, niobium, zirconium, molybdenum, tungsten, or an alloy of these metals with nickel or titanium. The layer thicknesses of the semiconducting layers and the layer thicknesses of the metallic layers are 3 nm to 100 nm, in particular 5 nm to 20 nm. The thickness of the layer stack is between 20 nm and 300 nm.

In a first exemplary embodiment, a semiconducting layer such as germanium, for example, is directly applied to the silicon carbide substrate. A metallic layer is applied to the semiconducting layer. In other words, the layer stack includes a semiconducting layer made of germanium and a metallic layer made of nickel, for example. Alternatively, the semiconducting layer is made of germanium doped with antimony or phosphorus. The advantage is that this layer may be applied via cathode sputtering.

In a second exemplary embodiment, a semiconducting layer such as germanium, for example, is directly applied to the silicon carbide substrate. Metallic layers and semiconducting layers are applied to this semiconducting layer in alternation. The layer stack includes, for example, a first semiconducting layer made of germanium, a first metallic layer made of nickel, a second semiconducting layer made of germanium, and a second metallic layer made of vanadium. The first metallic layer and the second metallic layer may be interchanged. This means that a layer sequence of germanium, vanadium, germanium, and nickel results. Alternatively, the first metallic layer may include a nickel-vanadium alloy, and the second metallic layer may include a vanadium-nickel alloy.

In a third exemplary embodiment, the layer stack includes three layers: two metallic layers and a semiconducting layer. One metallic layer includes nickel, the semiconducting layer includes germanium, and the other metallic layer includes vanadium, for example. Either the nickel layer or the vanadium layer may be situated directly on the silicon carbide substrate. Alternatively, the other metallic layer includes a nickel-vanadium alloy.

In a fourth exemplary embodiment, the layer stack includes three layers: two metallic layers and a semiconducting layer. One metallic layer includes nickel, the semiconducting layer includes germanium, and the other metallic layer includes vanadium, for example. The individual layers may be situated one on top of the other in any desired sequence. In other words, the layer sequence of the layer stack results from permutation of these three layers. This means that the two metallic layers may also follow one another in direct succession. The layer stack thus contains, for example, nickel, vanadium, and germanium, or germanium, nickel, and vanadium, as a layer sequence. The sequence of the nickel layer and the vanadium layer may likewise be interchanged.

In a fifth exemplary embodiment, the layer stack includes two layers. The semiconducting layer made of germanium is directly applied to the silicon carbide substrate, in particular on the crystallographic C-side. The metallic layer includes nickel and vanadium, which are applied to the semiconducting layer from a joint sputter object via physical gas phase deposition.

A liquid phase of the layer stack is produced in a point-by-point manner in a subsequent step 120, a surface of the layer stack being scanned by use of laser beams. The laser beams have a diameter of 10 µm to 100 µm. The pulse repetition frequency of the laser beams is between 10 kHz and 50 kHz. The pulse duration of the laser beam is between 10 ns and 100 ns. The typical maximum output power of the laser, necessary for this purpose, is between 1 W and 100 W. The laser is set in such a way that the laser beams transmit at least an energy density of 1 J/cm2, in particular 1.5 to 3 J/cm2, per pulse onto a surface of the layer stack. In the process, the metallic elements nickel or titanium react with the silicon of the silicon carbide substrate. The additional metallic elements such as vanadium function as a binding element for the carbon that forms due to the chemical reaction of the silicon carbide with nickel or titanium under laser irradiation. Due to the laser treatment, the individual elements from the layer stack intermix, resulting in a mixed layer on the rear side of the silicon carbide substrate, at whose transition to the silicon carbide substrate an ohmic contact results.

FIG. 2 shows an ohmic contact 200 on a rear side, in particular a crystallographic C-side, of a silicon carbide substrate 202. For example, the active regions of a power transistor are situated on a front side of silicon carbide substrate 202 that is oppositely situated from the rear side of silicon carbide substrate 202. This is not shown in FIG. 2. As the result of a laser treatment, a layer 201 that includes semiconducting elements and metallic elements is situated on the rear side of silicon carbide substrate 202. This means that ohmic contact 200 is situated at the transition between silicon carbide substrate 202 and layer 201. The semiconducting elements in layer 201 are made of germanium. Layer 201 includes at least nickel or titanium as metallic elements. In addition, layer 201 may include metallic elements such as vanadium, tantalum, niobium, zirconium, molybdenum, or tungsten. These additional metallic elements function as a getter element or binder element for the carbon that forms due to the chemical reaction of the silicon carbide with nickel or titanium under laser irradiation. The contact resistance between silicon carbide substrate 202 and layer 201 has a value of less than 100 µΩ/cm2 at a current density greater than 3 A/mm2.

Power transistors such as MOSFETs may include the ohmic contacts according to the present invention. These power transistors are used in power electronics components such as inverters for electric vehicles or hybrid vehicles, inverters for photovoltaic systems and wind turbines, and in traction drives and high-voltage rectifiers.

1-13. (canceled)

14. A method for producing an ohmic contact on a crystallographic C-side of a silicon carbide substrate, comprising the following steps:
applying a layer stack to the crystallographic C-side of the silicon carbide substrate, the layer stack including at least one semiconducting layer containing germanium and at least one metallic layer; and
producing a point-by-point liquid phase of the layer stack by scanning a surface of the layer stack using laser beams.

15. The method as recited in claim 14, wherein semiconducting layers and metallic layers are applied to the crystallographic C-side of the silicon carbide substrate in alternation.

16. The method as recited in claim 14, wherein nickel or titanium are applied as the metallic layers.

17. The method as recited in claim 16, wherein (i) vanadium or (ii) tantalum or (iii) niobium or (iii) zirconium or (iv) molybdenum or (v) tungsten or (vi) an alloy of (i) or (ii) or (iii) or (iv), with nickel or titanium, are applied as the metallic layers.

18. The method as recited in claim 14, wherein layer thicknesses of the semiconducting layers and layer thicknesses of the metallic layers of 3 nm to 100 nm are applied.

19. The method as recited in claim 14, wherein the at least one semiconducting layer containing germanium is applied to the silicon carbide substrate as a first layer.

20. The method as recited in claim 14, wherein the laser beams for producing the point-by-point liquid phase of the layer stack have a diameter of 10 µm to 100 µm.

21. The method as recited in claim 14, wherein the laser beams transmit at least an energy density of 1 J/cm2 onto a surface of the layer stack.

22. The method as recited in claim 14, wherein a pulse repetition frequency of the laser beams is between 10 kHz and 50 kHz.

23. An ohmic contact on a crystallographic C-side of a silicon carbide substrate, comprising:
a layer that includes semiconducting elements containing germanium and metallic elements situated on the crystallographic C-side of the silicon carbide substrate, the layer being a result of a laser treatment.

24. The ohmic contact as recited in claim 23, wherein the metallic elements include nickel or titanium.

25. The ohmic contact as recited in claim 24, wherein the metallic elements include vanadium or tantalum or niobium or zirconium or molybdenum or tungsten.

26. The ohmic contact as recited in claim 23, wherein a contact resistance between the silicon carbide substrate and the layer has a value of less than 100 µΩ/cm2 at a current density greater than 3 A/mm2.
